(19) United States
(12) Patent Application Publication
(10) Pub. No.: US 2019/0131115 A1
(43) Pub. Date: May 2, 2019

(54) SUPPORT UNIT AND SUBSTRATE TREATING APPARATUS INCLUDING THE SAME

(71) Applicant: SEMES CO., LTD., Chungcheongnam-do (KR)

(72) Inventors: Jamyung Gu, Chungcheongnam-do (KR); Jungmo Gu, Gyeonggi-do (KR); Jun Ho Lee, Chungcheongnam-do (KR); Jong Hwan An, Gyeonggi-do (KR); Saewon Na, Chungcheongbuk-do (KR)

(21) Appl. No.: 16/174,679

(22) Filed: Oct. 30, 2018

(30) Foreign Application Priority Data
Oct. 30, 2017 (KR) 10-2017-0142659

(51) Int. Cl. H01J 37/32; H01L 21/67; H01L 21/3065; H03H 7/01

(52) U.S. Cl. CPC H01J 37/32642; H01L 21/67069; H01L 21/3065; H01J 2237/334; H01J 37/3244; H01J 37/32724; H03H 7/0115

(57) ABSTRACT

The substrate treating apparatus includes a chamber having a treatment space in the interior thereof, a support unit configured to support a substrate, a gas supply unit configured to supply a gas into the treatment space, and a plasma source configured to generate plasma, wherein the support unit includes a support plate, on which the substrate is positioned, a ring assembly surrounding a circumference of the support plate and having a ring-shaped electrode, and a voltage applying unit configured to control an incident angle of the plasma onto the substrate by applying a voltage to the ring-shaped electrode, and wherein the voltage applying unit includes a base plate of a conductive material, a DC power source configured to apply a DC voltage to the base plate, and a plurality of connecting bodies connecting the base plate and the ring-shaped electrode, formed of a conductive material.

### CROSS-REFERENCE TO RELATED APPLICATIONS

This application claims priority under 35 U.S.C. § 119 to Korean Patent Application No. 10-2017-0142659 filed on Oct. 30, 2017, in the Korean Intellectual Property Office, the disclosures of which are incorporated by reference herein in their entireties.

### BACKGROUND

Embodiments of the inventive concept described herein relate to a substrate treating apparatus and a substrate treating method, and more particularly to a substrate treating apparatus that adjusts an incident angle of plasma onto a substrate, and a substrate treating method.

A semiconductor manufacturing process may include a process of treating a substrate by using plasma. For example, in an etching process of the semiconductor process, a thin film on the substrate may be removed by using plasma.

In a substrate treating process, such as an etching process using plasma, a plasma area has to be expanded to a peripheral area of the substrate to increase the process uniformity to the periphery of the substrate. To achieve this, a ring member that may exhibit an electric field coupling is provided to surround a substrate support, and a ring-shaped insulator is used to electrically isolate the ring assembly from a lower module of the equipment.

Meanwhile, the ring member includes a material, such as Si, SiC, or quartz, and an electric potential of a plasma sheath may be lowered as the ring member is worn out or etched due to collision with ions generated during a plasma process over time. Accordingly, while plasma ions have an angle on a substrate as in FIG. 7 before the ring member is worn out or etched, the angle of the ions that are input to an extreme edge of the substrate is gradually deflected toward the center of the substrate as in FIG. 8 while the ring member is worn out or etched. Accordingly, the process changes and as a result, the profile of the pattern of the substrate is deflected.

### SUMMARY

Embodiments of the inventive concept provide a support unit that may control an incident angle of plasma onto a substrate, and a substrate treating apparatus including the same.

The problems that are to be solved by the inventive concept are not limited to the above-mentioned problems, and the unmentioned problems will be clearly understood by those skilled in the art to which the inventive concept pertains from the specification and the accompanying drawings.

In accordance with an aspect of the inventive concept, there is provided a substrate treating apparatus including a chamber having a treatment space in the interior thereof, a support unit configured to support a substrate in the treatment space, a gas supply unit configured to supply a gas into the treatment space, and a plasma source configured to generate plasma from the gas, wherein the support unit further includes a support plate, on which the substrate is positioned, a ring assembly surrounding a circumference of the support plate and having a ring-shaped electrode, and a voltage applying unit configured to control an incident angle of the plasma onto the substrate by applying a voltage to the ring-shaped electrode, and wherein the voltage applying unit includes a base plate of a conductive material, a DC power source configured to apply a DC voltage to the base plate, and a plurality of connecting bodies connecting the base plate and the ring-shaped electrode, formed of a conductive material, and spaced apart from each other.

The ring assembly may include a focus ring surrounding the substrate positioned on the support plate, and a lower ring of an insulation material surrounding the support plate and provided under the focus ring.

The ring-shaped electrode may be provided within the lower ring and the plurality of connecting bodies may be provided at the same interval.

The base plate may have a ring shape and the plurality of connecting bodies have a bar shape.

The base plate may include a connector provided on one surface of the base plate, and the DC power source may be connected to the connector of the base plate.

The ring assembly may further include a metallic ring of a metallic material provided between the focus ring and the lower ring.

The ring assembly may further include a quartz ring of a quartz material provided between the focus ring and the lower ring.

The plurality of connecting bodies may be three bars of a conductive material and are spaced apart from each other by 120 degrees on the base plate.

The voltage applying unit may further include a DC filter configured to interrupt a specific RF frequency from the voltage supplied by the DC power source.

The DC filter may include an inductor and a capacitor.

In accordance with another aspect of the inventive concept, there is provided a support unit for supporting a substrate in a plasma process chamber, the support unit including a support plate, on which the substrate is positioned, a ring assembly surrounding a circumference of the support plate and having a ring-shaped electrode, and a voltage applying unit configured to control an incident angle of the plasma onto the substrate by applying a voltage to the ring-shaped electrode, and wherein the voltage applying unit further includes a base plate of a conductive material, a DC power source configured to apply a DC voltage to the base plate, and a plurality of connecting bodies connecting the base plate and the ring-shaped electrode, formed of a conductive material, and spaced apart from each other.

The ring assembly may further include a focus ring surrounding the substrate positioned on the support plate, and a lower ring of an insulation material surrounding the support plate and provided under the focus ring.

The ring-shaped electrode may be provided within the lower ring and the plurality of connecting bodies may be provided at the same interval.

The base plate may have a ring shape and the plurality of connecting bodies may have a bar shape.

The plurality of connecting bodies may be three bars of a conductive material and may be spaced apart from each other by 120 degrees on the base plate.

The voltage applying unit may further include a DC filter configured to interrupt a specific RF frequency from the voltage supplied by the DC power source.

In accordance with another aspect of the inventive concept, there is provided a method for controlling a substrate treating apparatus, the method including applying a DC voltage to the ring shaped electrode, and controlling an incident angle of the plasma onto the substrate by adjusting the DD voltage.

### BRIEF DESCRIPTION OF THE FIGURES

The above and other objects and features of the inventive concept will become apparent by describing in detail exemplary embodiments thereof with reference to the accompanying drawings.

FIG. 1 is an exemplary view illustrating a substrate treating apparatus according to an embodiment of the inventive concept;

FIG. 2 is an exemplary sectional view illustrating a support unit according to an embodiment of the inventive concept;

FIG. 3 is a view illustrating a base plate according to an embodiment of the inventive concept;

FIG. 4 is a view illustrating a ring-shaped electrode according to an embodiment of the inventive concept;

FIG. 5 is a circuit diagram illustrating another DC filter according to an embodiment of the inventive concept;

FIG. 6 is a flowchart illustrating a control method according to an embodiment of the inventive concept; and

FIGS. 7 and 8 are views for explaining a problem of a substrate treating apparatus according to the related art.

### DETAILED DESCRIPTION

Hereinafter, exemplary embodiments of the inventive concept will be described in detail with reference to the accompanying drawings.

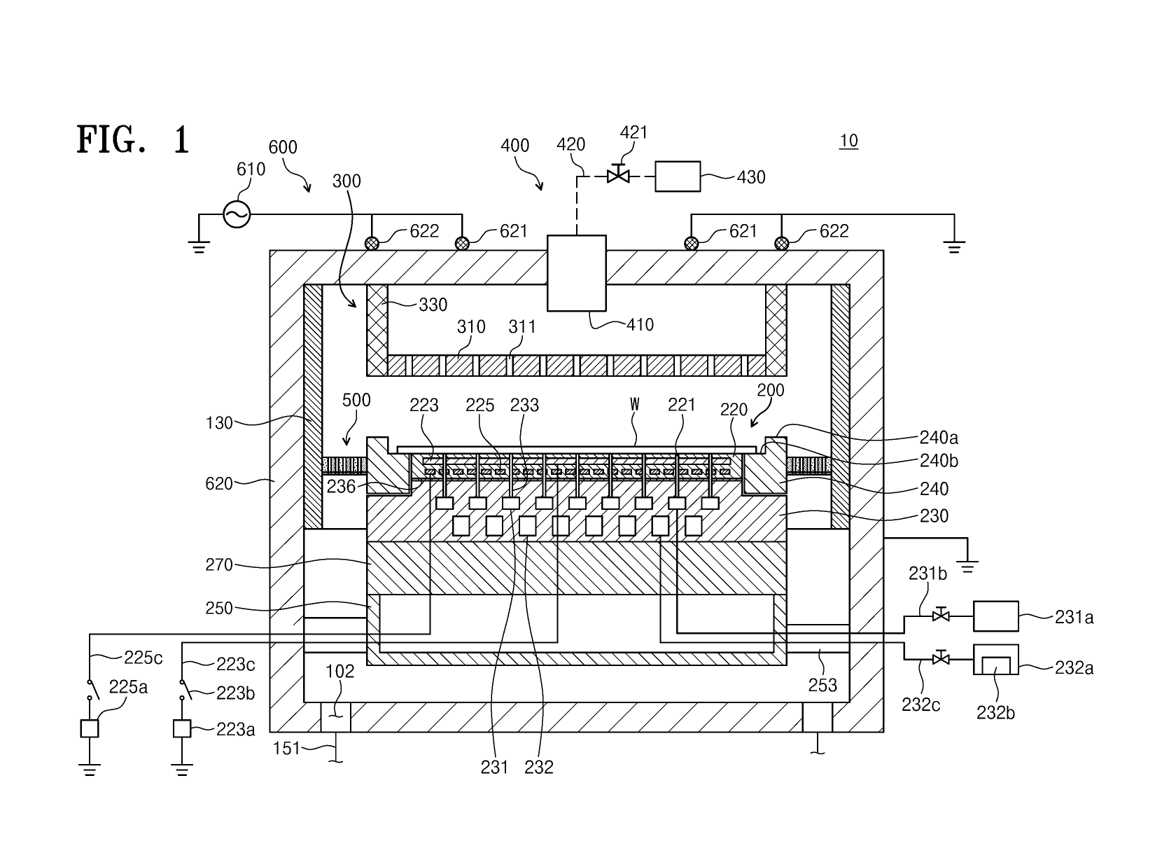

FIG. 1 is an exemplary view illustrating a substrate treating apparatus according to an embodiment of the inventive concept.

Referring to FIG. 1, the substrate treating apparatus 10 treats a substrate W by using plasma. For example, the substrate treating apparatus 10 may perform an etching process on the substrate W. The substrate treating apparatus 10 may include a chamber 620, a support unit 200, a shower head 300, a gas supply unit 400, a baffle unit 500, and a plasma generating unit 600.

The chamber 620 may provide a treatment space in which a substrate treating process is performed in the interior thereof. The chamber 620 may have a treatment space in the interior thereof, and may have a closed shape. The chamber 620 may be formed of a metallic material. Further, the chamber 620 may be formed of aluminum. The chamber 620 may be grounded. An exhaust hole 102 may be formed on a bottom surface of the chamber 620. The exhaust hole 102 may be connected to an exhaust line 151. The reaction side-products generated in the process and gases left in the interior space of the chamber may be discharged to the outside through the exhaust line 151. The pressure of the interior of the chamber 620 may be reduced to a specific pressure through an exhaustion process.

According to an embodiment, a liner 130 may be provided in the interior of the chamber 620. Upper and lower surfaces of the liner 130 may have an opened cylindrical shape. The liner 130 may be configured to contact an inner surface of the chamber 620. The liner 130 may prevent an inner wall of the chamber 620 from being damaged due to arc discharging by protecting the inner wall of the chamber 620. Further, the liner 130 may prevent the impurities generated during the substrate treating process from being deposited to the inner wall of the chamber 620. Optionally, the liner 130 may not be provided.

The support unit 200 may be located in the interior of the chamber 620. The support unit 200 may support the substrate W. The support unit 200 may include a support plate 210 configured to suction the substrate W by using an electrostatic force. Unlike this, the support unit 200 may support the substrate W in various methods such as mechanical clamping. Hereinafter, the support unit 200 including the support plate 210 will be described.

The support unit 200 may include a support plate 210, a ring assembly 240, a lower cover 250, and a plate 270. The support unit 200 may be located in the interior of the chamber 620 to be spaced upwards apart from the bottom surface of the chamber 620.

The support plate 210 may include a dielectric plate 220 and a body 230. The support plate 210 may support the substrate W. The dielectric plate 220 may be located at an upper end of the support plate 210. The dielectric plate 220 may be formed of a dielectric substance and may have a disk shape. The substrate W may be positioned on an upper surface of the dielectric plate 220. The upper surface of the dielectric plate 220 may have a radius that is smaller than that of the substrate W. Accordingly, an extreme edge of the substrate W may be located on an outer side of the dielectric plate 220.

A first electrode 223, a heating unit 225, and a first supply passage 221 may be included in the interior of the dielectric plate 220. The first supply passage 221 may extend from an upper surface to a bottom surface of the dielectric plate 210. A plurality of first supply passages 221 are formed to be spaced apart from each other to be provided as passages through which a heat transfer medium is supplied to the bottom surface of the substrate W.

The first electrode 223 may be electrically connected to a first power source 223a. The first power source 223a may include a DC power source. A switch 223b may be installed between the first electrode 223 and the first power source 223a. The first electrode 223 may be electrically connected to the first power source 223a by switching on and off the switch 223b. If the switch 223b is switched on, a DC current may be applied to the first electrode 223. An electrostatic force may be applied between the first electrode 223 and the substrate W by a current applied to the first electrode 223, and the substrate W may be suctioned to the dielectric plate 220 by an electrostatic force.

The heating unit 225 may be located under the first electrode 223. The heating unit 225 may be electrically connected to a second power source 225a. The heating unit 225 may generate heat by a resistance due to a current applied to the second power source 225a. The generated heat may be transferred to the substrate W through the dielectric plate 220. The substrate W may be maintained at a specific temperature by the heat generated by the heating unit 225. The heating unit 225 may include a spiral coil.

The body 230 may be located under the dielectric plate 220. A bottom surface of the dielectric plate 220 and an upper surface of the body 230 may be bonded to each other by an adhesive 236. The body 230 may be formed of aluminum. An upper surface of the body 230 may be located such that a central area thereof is higher than an extreme edge thereof. The central area of the upper surface of the body 230 may have an area corresponding to a bottom surface of the dielectric plate 220, and may be bonded to the bottom surface of the dielectric plate 220. The body 230 may have first circulation passages 231, second circulation passages 232, and second supply passages 233 in the interior thereof.

The first circulation passages 231 may be provided as passages through which a heat transfer medium circulates. The first circulation passages 231 may be formed in the interior of the body 230 to have a spiral shape. Further, the first circulation passages 231 may be disposed such that passages having ring shapes of different radii have the same center. The first circulation passages 231 may communicate with each other. The first circulation passages 231 may be formed at the same height.

The second circulation passages 232 may be provided as passages through which a cooling fluid circulates. The second circulation passages 232 may be formed in the interior of the body 230 to have a spiral shape. Further, the second circulation passages 232 may be disposed such that passages having ring shapes of different radii have the same center. The second circulation passages 232 may communicate with each other. The second circulation passages 232 may have a sectional area that is larger than that of the first circulation passage 231. The second circulation passages 232 may be formed at the same height. The second circulation passages 232 may be located under the first circulation passages 231.

The second supply passages 233 may extend upwards from the first circulation passages 231, and may be provided on an upper surface of the body 230. The number of the second supply passages 233 corresponds to the first supply passages 221 and may connect the first circulation passages 231 and the first supply passages 221.

The first circulation passages 231 may be connected to a heat transfer medium storage 231a through heat transfer medium supply lines 231b. A heat transfer medium may be stored in the heat transfer medium storage 231a. The heat transfer medium may include an inert gas. According to an embodiment, the heat transfer medium may include a helium (He) gas. The helium gas may be supplied to the first circulation passages 231 through supply lines 231b, and may be supplied to the bottom surface of the substrate W after sequentially passing through the second supply passages 233 and the first supply passages 221. The helium gas may function as a medium by which the heat transferred from plasma to the substrate W is transferred to the support plate 210.

The second circulation passages 232 may be connected to the cooling fluid storage 232a through the cooling fluid supply lines 232c. The cooling fluid storage 232a may store a cooling fluid. A cooler 232b may be provided in the cooling fluid storage 232a. The cooler 232b may cool the cooling fluid to a specific temperature. Unlike this, the cooler 232b may be installed on the cooling fluid supply line 232c. The cooling fluid supplied to the second circulation passages 232 through the cooling fluid supply lines 232c may cool the body 230 while circulating along the second circulation passages 232. The body 230 may cool the dielectric plate 220 and the substrate W together while being cooled to maintain the substrate W at a specific temperature.

The body 230 may include a metal plate. According to an embodiment, the whole body 230 may be formed of a metal plate.

The ring assembly 240 may be disposed at an extreme edge of the support plate 210. The ring assembly 240 may have a ring shape and may be disposed along a circumference of the dielectric plate 220. An upper surface of the ring assembly 240 may be located such that an outer side 240a thereof is higher than an inner side 240b thereof. The inner side 240b of the upper surface of the ring assembly 240 may be located at the same height as that of the upper surface of the dielectric plate 220. The inner side 240b of the upper surface of the ring assembly 240 may support the extreme edge of the substrate W located on an outside of the dielectric plate 220. The outside 240a of the ring assembly 240 may be configured to surround the extreme edge of the substrate W. The ring assembly 240 may control an electromagnetic field such that densities of plasma are uniformly distributed in the whole area of the substrate W. Accordingly, plasma is uniformly formed over the whole area of the substrate W such that the areas of the substrate W may be uniformly etched.

In detail, the ring assembly 240 may include a focus ring 241 surrounding the substrate positioned on the support plate 210, and a lower ring 242 surrounding the support plate 210 and provided on a lower side of the focus ring 241. Here, the lower ring 242 is formed of an insulation material. Further, the lower ring 242 may include a ring-shaped electrode 261 in the interior thereof. A plasma sheath in the chamber 620 may be adjusted by adjusting a voltage applied to the ring-shaped electrode 261, and accordingly, an incident angle of the plasma onto the substrate may be controlled.

A first ring 243 may be provided between the focus ring 241 and the lower ring 242. Here, the first ring 243 may be a metallic ring of a metallic material. As an example, the metallic ring may be formed of aluminum, but the inventive concept is not limited thereto and the metallic ring may be formed of various metallic materials. As another example, the first ring 243 may be a quartz ring of a quartz material. When the first ring 243 is a quartz ring, an incident angle of plasma onto the substrate may be larger than when the first ring 243 is a metallic ring. Further, a second ring 244 may be provided on an outside of the focus ring 241. Here, the second ring 244 may be formed of an insulator.

The lower cover 250 may be located at a lower end of the support unit 200. The lower cover 250 may be spaced upwards apart from the bottom surface of the chamber 620. An open-topped space 255 may be formed in the interior of the lower cover 250. The outer radius of the lower cover 250 may have the same as the outer radius of the body 230. A lift pin module (not illustrated) that moves the transferred substrate W from a transfer member on the outside to the support plate 210 may be located in the interior space 255 of the lower cover 250. The lift pin module (not illustrated) may be spaced apart from the lower cover 250 by a specific interval. A bottom surface of the lower cover 250 may be formed of a metallic material. The interior space 255 of the lower cover 250 may be provided with air. Because the dielectric constant of air is lower than that of an insulator, the air may reduce an electromagnetic field in the interior of the support unit 200.

The lower cover 250 may have a connecting member 253. The connecting member 253 may connect an outer surface of the lower cover 250 and an inner wall of the chamber 620. A plurality of connecting members 253 may be provided on an outer surface of the lower cover 250 at a specific interval. The connecting member 253 may support the support unit 200 in the interior of the chamber 620. Further, the lower cover 250 may be connected to the inner wall of the chamber 620 to be electrically grounded. A first power line 223c connected to the first power source 223a, a second power line 225c connected to the second power source 225a, a heat transfer medium supply line 231b connected to the heat transfer medium storage 231a, and a cooling fluid supply line 232c connected to the cooling fluid storage 232a may extend into the lower cover 250 through the interior space 255 of the connecting member 253.

A plate 270 may be located between the support plate 210 and the lower cover 250. The plate 270 may cover an upper surface of the lower cover 250. The plate 270 may have a sectional area corresponding to the body 230. The plate 270 may include an insulator. According to an embodiment, one or more plates 270 may be provided. The plate 270 may function to increase an electrical distance between the body 230 and the lower cover 250.

The shower head 300 may be located above the support unit 200 in the interior of the chamber 620. The shower head 300 may be located to face the support unit 200.

The shower head 300 may include a gas dispersing plate 310 and a support 330. The gas dispersing plate 310 may be spaced downwards apart from an upper surface of the chamber 620. A space may be formed between the gas dispersing plate 310 and the upper surface of the chamber 620. The gas dispersing plate 310 may have a plate shape having a specific thickness. The bottom surface of the gas dispersing plate 310 may be anodized to prevent generation of an arc by plasma. The gas dispersing plate 310 may have the same shape and cross-section as those of the support unit 200. The gas dispersing plate 310 may include a plurality of ejection holes 311. The ejection holes 311 may vertically pass through the upper surface and the lower surface of the gas dispersing plate 310. The gas dispersing plate 310 may include a metallic material.

The support 330 may support a side of the gas dispersing plate 310. An upper end of the support 330 may be connected to the upper surface of the chamber 620, and a lower end of the support 330 may be connected to a side of the gas dispersing plate 310. The body 330 may include a nonmetallic plate.

The gas supply unit 400 may supply a process gas into the interior of the chamber 620. The gas supply unit 400 may include a gas supply nozzle 410, a gas supply line 420, and a gas storage unit 430. The gas supply nozzle 410 may be installed at a central portion of the upper surface of the chamber 620. An ejection hole may be formed on the bottom surface of the gas supply nozzle 410. A process gas may be supplied into the interior of the chamber 620 through the ejection hole. The gas supply unit 400 may connect the gas supply nozzle 410 and the gas storage unit 430. The gas supply line 420 may supply the process gas stored in the gas storage unit 430 to the gas supply nozzle 410. A valve 421 may be installed in the gas supply line 420. The valve 421 may open and close the gas supply line 420, and may adjust a flow rate of the process gas supplied through the gas supply line 420.

The baffle unit 500 may be located between the inner wall of the chamber 620 and the support unit 200. The baffle 510 may have an annular ring shape. The baffle 510 may have a plurality of through-holes 511. The process gas provided into the chamber 620 may pass through through-holes 511 of the baffle 510 to be exhausted through an exhaust hole 102. The flow of the process gas may be controlled according to the shape of the baffle 510 and the shape of the through-holes 511.

The plasma generating unit 600 may excite a process gas in the chamber 620 into a plasma state. According to an embodiment of the inventive concept, the plasma generating unit 600 may be of an inductively coupled plasma (ICP) type. In this case, as illustrated in FIG. 1, the plasma generating unit 600 may include a high frequency power source 610 configured to supply high frequency power, and a first coil 621 and a second coil 622 electrically connected to the high frequency power source 610 to receive high frequency power.

Although it has been described in the specification that the plasma generating unit 600 is of an inductively coupled plasma (ICP) type, the inventive concept is not limited thereto but the plasma generating unit 600 may be of a capacitively coupled plasma (CCP) type.

When the plasma source of a CCP type is used, an upper electrode and a lower electrode, that is, the body may be included in the chamber 620. The upper electrode and the lower electrode may be vertically disposed in parallel to each other while a treatment space is interposed therebetween. The upper electrode as well as the lower electrode may receive RF signals from an RF power source to receive energy for generating plasma, and the number of RF signals applied to the electrodes is not limited to one as illustrated. An electromagnetic field may be formed in a space between the two electrodes, and the process gas supplied into the space may be excited into a plasma state. A substrate treating process is performed by using the plasma.

Referring to FIG. 1 again, the first coil 621 and the second coil 622 may be disposed at locations that face the substrate W. For example, the first coil 621 and the second coil 622 may be installed above the chamber 620. The diameter of the first coil 621 may be smaller than the diameter of the second coil 622 such that the first coil is located inside the upper side of the chamber 610 and the second coil 622 is located outside the upper side of the chamber 610. The first coil 621 and the second coil 622 may receive high frequency power from the high frequency power source 610 to induce a time-variable magnetic field in the chamber, and accordingly, the process gas supplied to the chamber may be excited by plasma.

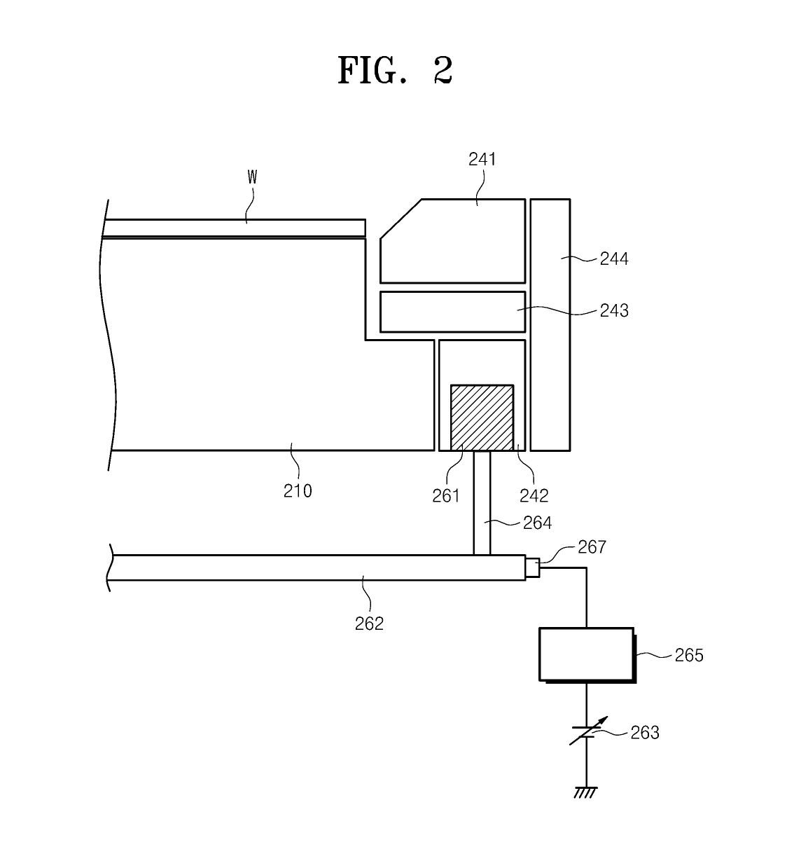

FIG. 2 is an exemplary sectional view illustrating a support unit according to an embodiment of the inventive concept.

Referring to FIG. 2, the support unit 200 according to an embodiment of the inventive concept includes a support plate 210, a ring assembly 240, and a voltage applying unit 260.

The support plate 210 supports the substrate, and suctions the substrate by using an electrostatic force. The ring assembly 240 surrounds a circumference of the support plate 210, and has a ring-shaped electrode 261. The ring assembly 240 may include a focus ring 241, a lower ring 242, a first ring 243, and a second ring 244. The focus ring 241 may be configured to surround the substrate positioned on the support plate 210, and the lower ring 242 may be provided on a lower side of the focus ring 241 and may be configured to surround the support plate 210. The lower ring 242 may be formed of an insulation material, and may include a ring-shaped electrode 261 in the interior thereof. The first ring 243 is provided between the focus ring 241 and the lower ring 242. As an example, the first ring 243 may be a metallic ring of a metallic material. As another example, the first ring 243 may be a quartz ring of a quartz material. When the first ring 243 is a quartz ring, an incident angle of plasma onto the substrate may be larger than when the first ring 243 is a metallic ring. Further, a second ring 244 may be provided on an outside of the focus ring 241. Here, the second ring 244 may be formed of an insulator.

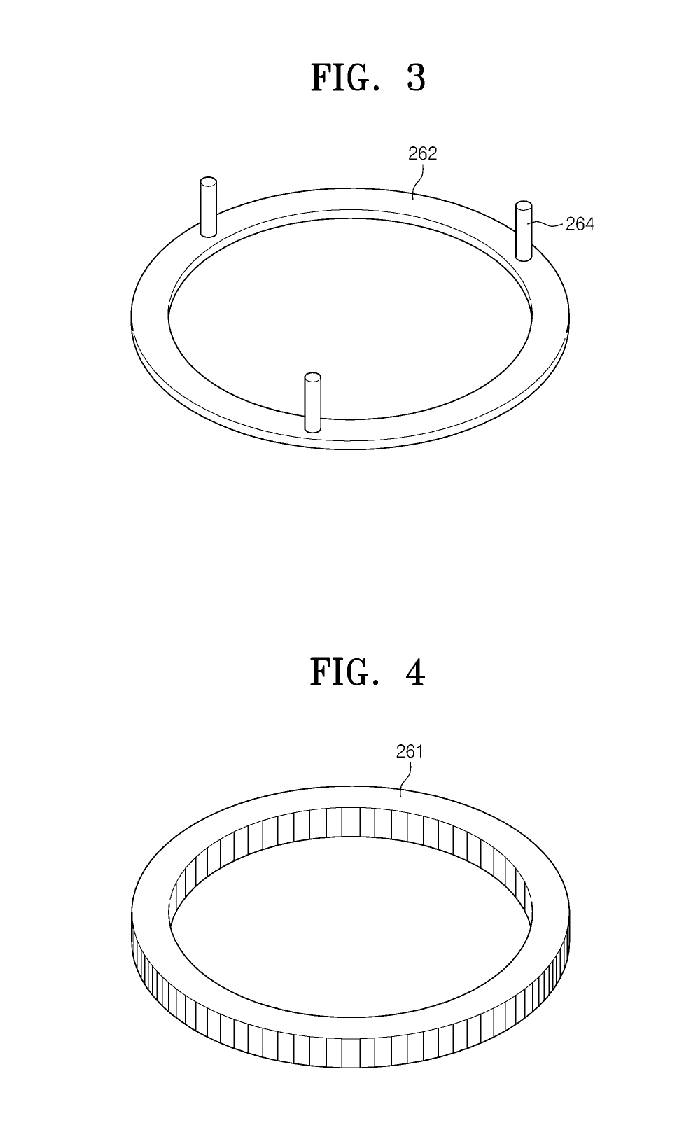

The voltage applying unit 260 includes a base plate 262, a DC power source 263, and a plurality of connecting bodies 264. The base plate 262 may be formed of a conductive material and may have a ring shape. The plurality of connecting bodies 264 may be provided on an upper surface of the base plate 262. The plurality of connecting bodies 264 may be provided to be spaced apart from each other while connecting the base plate 262 and the ring-shaped electrode 261. The plurality of connecting bodies 264 may be formed of a conductive material such that a voltage supplied by the DC power source 263 may be applied to the ring-shaped electrode 261. Further, the plurality of connecting bodies 264 may be provided to be spaced apart from each other at the same interval. As an example, as in FIG. 3, the plurality of connecting bodies 264 may be three bars of a conductive material, which are spaced apart from each other at an interval of 120 degrees on the ring-shaped base plate 262. Accordingly, because the plurality of connecting bodies 264 are provided on the upper surface of the ring-shaped base plate 262 to be spaced apart from each other at the same interval and a voltage is applied to a plurality of locations that are spaced apart from each other at the same interval in the ring-shaped electrode 261 as in FIG. 4, the voltage may be uniformly applied to the all areas of the ring-shaped electrode 261. As a result, the incident angle of plasma may be uniformly controlled in all the edge areas of the substrate. That is, according to an embodiment of the inventive concept, an asymmetry phenomenon that is caused by an unbalance of voltages due to the resistance of the ring-shaped electrode 261 may be alleviated.

Further, a connector 267 may be provided on one surface of the base plate 262 and the DC power source 263 is connected to the connector 267 so that a voltage may be applied to the ring-shaped electrode 261 through the base plate 262 and the plurality of connecting bodies 264.

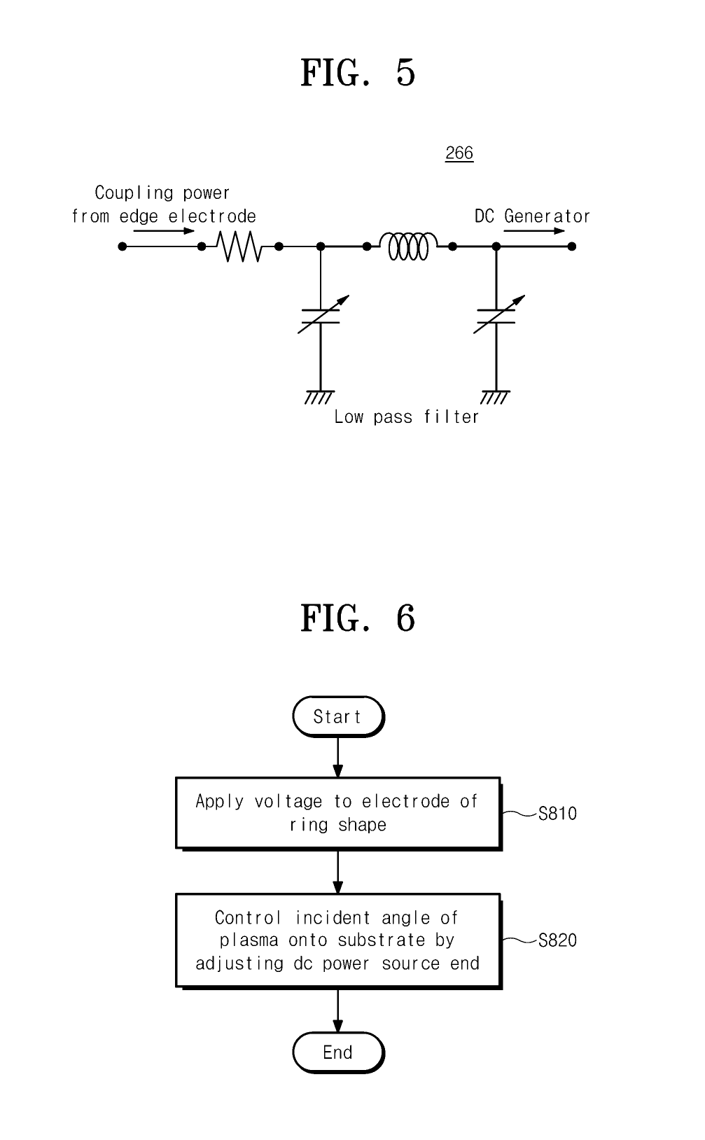

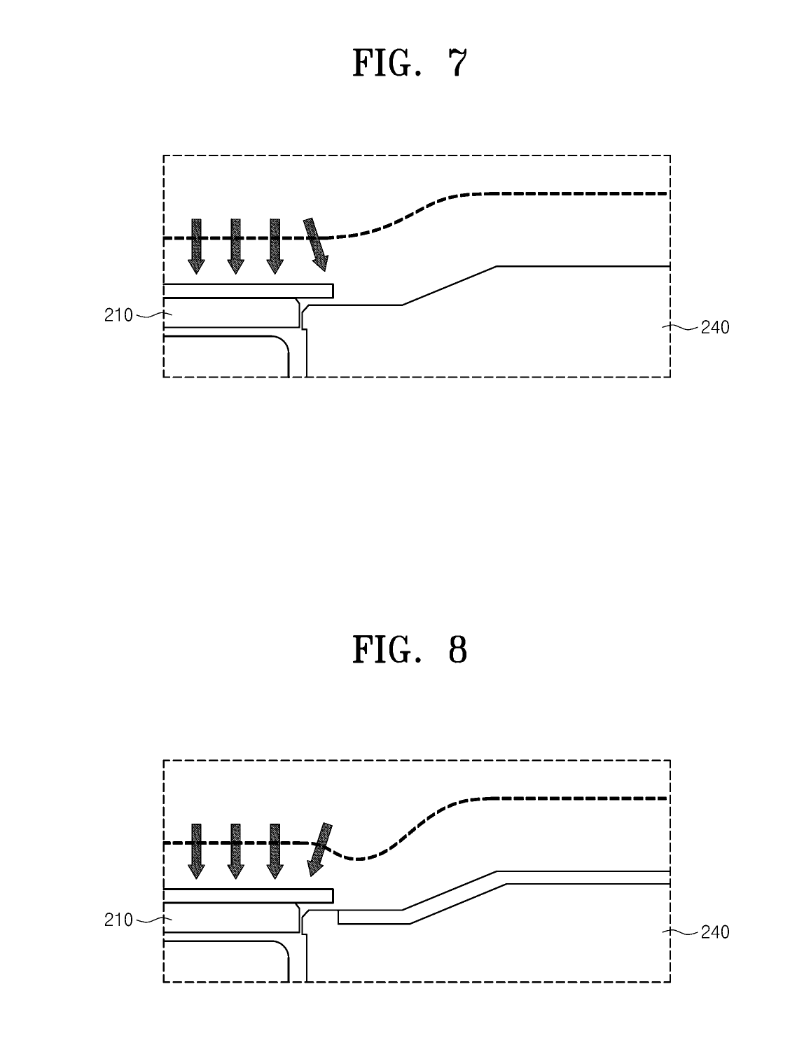

The DC power source 263 supplies a DC voltage. The voltage applying unit 260 according to an embodiment of the inventive concept may change a plasma sheath in the chamber 620 more than when a high-frequency voltage is supplied, by supplying a DC voltage to the ring-shaped electrode 261, and may easily control an incident angle of the plasma onto the substrate. Further, the voltage applying unit 260 may include a DC filter 265 connected to the DC power source 263, and may interrupt a specific RF frequency at the voltage supplied by the DC power source 263. The DC filter 265 may include an inductor and a capacitor. As an example, the DC filter 265 may include a resistor, an inductor, and a variable capacitor as in FIG. 5, and may allow only a DC voltage to be applied to the ring-shaped electrode 261 by interrupting an RF frequency, except for a DC voltage.

FIG. 6 is a flowchart illustrating a control method according to an embodiment of the inventive concept.

Referring to FIG. 6, the control method of the substrate treating apparatus according to an embodiment of the inventive concept may include an operation of applying a DC voltage to a ring-shaped electrode (S810), and an operation of controlling an incident angle of plasma onto a substrate by adjusting the DC voltage (S820).

As described above, according to various embodiments of the inventive concept, an incident angle of plasma onto a substrate may be easily controlled by applying a voltage to a ring-shaped electrode.

The effects of the inventive concept are not limited to the above-mentioned effects, and the unmentioned effects can be clearly understood by those skilled in the art to which the inventive concept pertains from the specification and the accompanying drawings.

It is noted that the above embodiments are suggested for understanding of the inventive concept and do not limit the scope of the inventive concept, and various modifiable embodiments also fall within the scope of the inventive concept. For example, the elements illustrated in the embodiments of the inventive concept may be individually implemented, and some of the individual elements may be coupled to each other to be implemented. It should be understood that the technical protection range of the inventive concept has to be determined by the technical spirit of the claims, and the technical protection range of the inventive concept is not limited to the lexical meaning of the claims but reaches even to the equivalent inventions.

What is claimed is:

1. A substrate treating apparatus comprising:
a chamber having a treatment space in the interior thereof;
a support unit configured to support a substrate in the treatment space;
a gas supply unit configured to supply a gas into the treatment space; and
a plasma source configured to generate plasma from the gas,
wherein the support unit further includes:
a support plate, on which the substrate is positioned;
a ring assembly surrounding a circumference of the support plate and having a ring-shaped electrode; and
a voltage applying unit configured to control an incident angle of the plasma onto the substrate by applying a voltage to the ring-shaped electrode, and
wherein the voltage applying unit includes:
a base plate of a conductive material;
a DC power source configured to apply a DC voltage to the base plate; and
a plurality of connecting bodies connecting the base plate and the ring-shaped electrode, formed of a conductive material, and spaced apart from each other.

2. The substrate treating apparatus of claim 1, wherein the ring assembly includes:
a focus ring surrounding the substrate positioned on the support plate; and
a lower ring of an insulation material surrounding the support plate and provided under the focus ring.

3. The substrate treating apparatus of claim 2, wherein the ring-shaped electrode is provided within the lower ring and the plurality of connecting bodies are provided at the same interval.

4. The substrate treating apparatus of claim 3, wherein the base plate has a ring shape and the plurality of connecting bodies have a bar shape.

5. The substrate treating apparatus of claim 4, wherein the base plate includes:
a connector provided on one surface of the base plate, and
wherein the DC power source is connected to the connector of the base plate.

6. The substrate treating apparatus of claim 2, wherein the ring assembly further includes:
a metallic ring of a metallic material provided between the focus ring and the lower ring.

7. The substrate treating apparatus of claim 2, wherein the ring assembly further includes:
a quartz ring of a quartz material provided between the focus ring and the lower ring.

8. The substrate treating apparatus of claim 4, wherein the plurality of connecting bodies are three bars of a conductive material and are spaced apart from each other by 120 degrees on the base plate.

9. The substrate treating apparatus of claim 1, wherein the voltage applying unit further includes:
a DC filter configured to interrupt a specific RF frequency from the voltage supplied by the DC power source.

10. The substrate treating apparatus of claim 9, wherein the DC filter includes an inductor and a capacitor.

11. A support unit for supporting a substrate in a plasma process chamber, the support unit comprising:
a support plate, on which the substrate is positioned;
a ring assembly surrounding a circumference of the support plate and having a ring-shaped electrode; and
a voltage applying unit configured to control an incident angle of the plasma onto the substrate by applying a voltage to the ring-shaped electrode, and
wherein the voltage applying unit further includes:
a base plate of a conductive material;
a DC power source configured to apply a DC voltage to the base plate; and
a plurality of connecting bodies connecting the base plate and the ring-shaped electrode, formed of a conductive material, and spaced apart from each other.

12. The support unit of claim 11, wherein the ring assembly further includes:
a focus ring surrounding the substrate positioned on the support plate; and
a lower ring of an insulation material surrounding the support plate and provided under the focus ring.

13. The support unit of claim 12, wherein the ring-shaped electrode is provided within the lower ring and the plurality of connecting bodies are provided at the same interval.

14. The support unit of claim 13, wherein the base plate has a ring shape and the plurality of connecting bodies have a bar shape.

15. The support unit of claim 14, wherein the plurality of connecting bodies are three bars of a conductive material and are spaced apart from each other by 120 degrees on the base plate.

16. The support unit of claim 11, wherein the voltage applying unit further includes:
a DC filter configured to interrupt a specific RF frequency from the voltage supplied by the DC power source.

17. A method for controlling the substrate treating apparatus claimed in claim 1, the method comprising:
applying a DC voltage to the ring shaped electrode; and
controlling an incident angle of the plasma onto the substrate by adjusting the DD voltage.
